(19) United States
(12) Patent Application Publication
(10) Pub. No.: US 2014/0353729 A1
(43) Pub. Date: Dec. 4, 2014

(54) SEMICONDUCTOR STRUCTURE AND METHOD FOR FORMING THE SAME

(71) Applicant: UNITED MICROELECTRONICS CORP., HSINCHU (TW)

(72) Inventor: Ching-Hung Kao, Hsinchu County (TW)

(73) Assignee: UNITED MICROELECTRONICS CORP., HSINCHU (TW)

(21) Appl. No.: 13/904,182

(22) Filed: May 29, 2013

(51) Int. Cl. H01L 29/66; H01L 29/78

(52) U.S. Cl. CPC H01L 29/66477; H01L 29/78
USPC 257/288; 438/595

(57) ABSTRACT

A semiconductor structure and a method for forming the same are provided. The method comprises following steps. A gate material film is formed on a substrate in a first device region and a second device region. The gate material film in the first device region is patterned to form a first patterned gate. A first spacer material film containing a nitride material is formed on the first patterned gate in the first device region and the gate material film in the second device region. The first spacer material film and the gate material film are patterned in the second device region to form a second patterned gate.

### BACKGROUND

1. Technical Field

The disclosure relates to a semiconductor structure and a method for forming the same, and more particularly to gate structures having different spacer structures and a method for forming the same.

2. Description of the Related Art

Along with the advance in semiconductor technology, semiconductor devices are kept being miniaturized, such that electronic products possess more and more functions when the size remains unchanged or become even smaller. Integrating various manufacturing processes is needed for the semiconductor devices in different regions. However, the complex processes increases manufacturing cost and production cycle time.

### SUMMARY

According to one aspect of the present disclosure, a method for forming a semiconductor structure is provided. The method comprises following steps. A gate material film is formed on a substrate in a first device region and a second device region. The gate material film is patterned to form a first patterned gate in the first device region. A first spacer material film is formed on the first patterned gate in the first device region and the gate material film in the second device region. The first spacer material film and the gate material film are patterned to form a second patterned gate in the second device region. A second spacer material film is formed on the first spacer material film in the first device region and the second patterned gate in the second device region. A portion of the first spacer material film and the second spacer material film are removed to form a first spacer structure consisting of the first spacer material film and the second spacer material film on a sidewall of the first patterned gate in the first device region and a second spacer structure consisting of the second spacer material film on a sidewall of the second patterned gate in the second device region.

According to another aspect of the present disclosure, a method for forming a semiconductor structure is provided. The method comprises following steps. A gate material film is formed on a substrate in a first device region and a second device region. The gate material film in the first device region is patterned to form a first patterned gate. A first spacer material film containing a nitride material is formed on the first patterned gate in the first device region and the gate material film in the second device region. The first spacer material film and the gate material film are patterned in the second device region to form a second patterned gate.

According to yet another aspect of the present disclosure, a semiconductor structure is provided. The semiconductor structure comprises a first patterned gate, a second patterned gate, a first spacer structure and a second spacer structure. The first patterned gate is on a substrate in a first device region. The second patterned gate is on the substrate in a second device region. The first spacer structure is on a sidewall of the first patterned gate. The first spacer structure consists of a first spacer material film and a second spacer material film on the first spacer material film. The second spacer structure is on a sidewall of the second patterned gate. The second spacer structure consists of the second spacer material film.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIGS. 1-6 illustrate a method for forming a semiconductor structure according to one embodiment.

### DETAILED DESCRIPTION

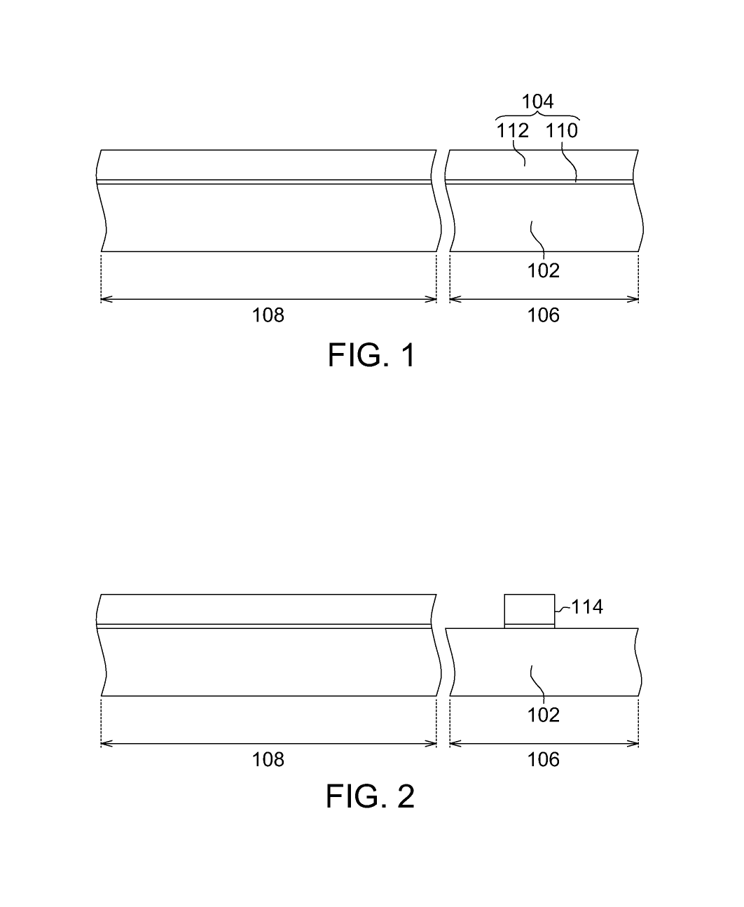

FIGS. 1-6 illustrate a method for forming a semiconductor structure according to one embodiment.

Referring to FIG. 1, a substrate 102 is provided. The substrate 102 may comprise a semiconductor material, such as Si, etc. A gate material film 104 is formed on the substrate 102 in a first device region 106 and a second device region 108. In one embodiment, the first device region 106 is for a logic device, and the second device region 108 is for a memory device. The gate material film 104 comprises a dielectric layer 110 formed on the substrate 102, and an electrode layer 112 formed on the dielectric layer 110. The dielectric layer 110 may comprise an oxide material or a nitride material, such as silicon oxide (SiO), silicon nitride (SiN), carbon doped silicon nitride (SiCN), or other suitable dielectric materials.

Referring to FIG. 2, the gate material film 104 is patterned to form a first patterned gate 114 in the first device region 106. The patterning step may comprise steps of forming a patterned photoresist (not shown) on the gate material film 104, removing a portion of the gate material film 104 exposed by an opening of the patterned photoresist, and then removing the patterned photoresist. In some embodiments, before the patterned photoresist is removed, a LDD doping step is performed to the substrate 102 outside of the first patterned gate 114 in the first device region 106 by using the patterned photoresist as a mask layer.

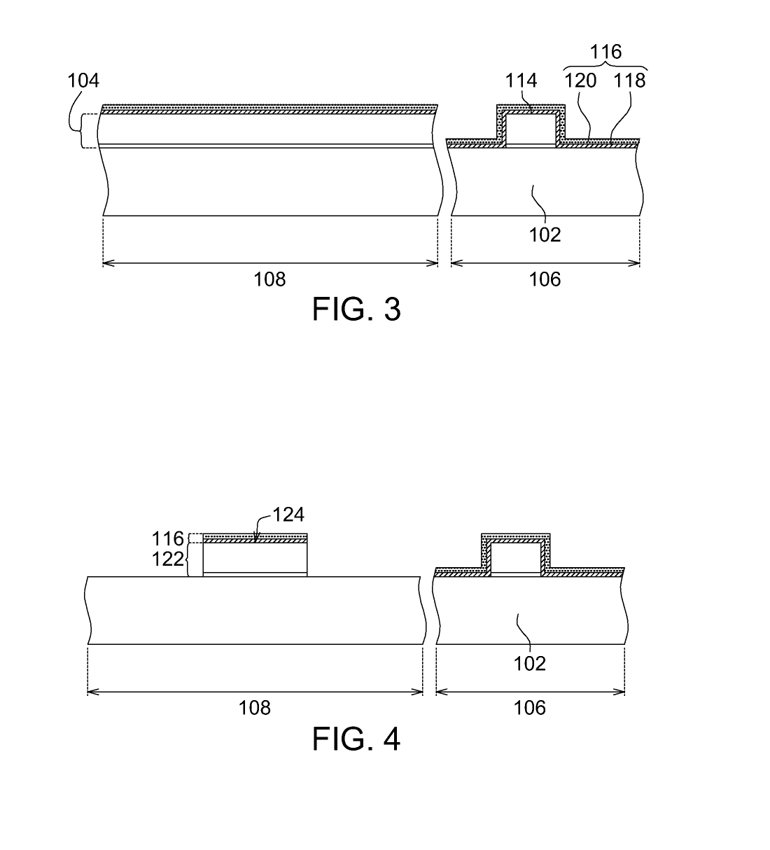

Referring to FIG. 3, a first spacer material film 116 is formed on the first patterned gate 114 and the substrate 102 in the first device region 106 and the gate material film 104 in the second device region 108. In one embodiment, the first spacer material film 116 comprises a first dielectric film 118 and a second dielectric film 120 formed on the first dielectric film 118.

Referring to FIG. 4, the first spacer material film 116 and the gate material film 104 in the second device region 108 is patterned to form a second patterned gate 122. By this step, the first spacer material film 116 in the second device region 108 is remained only on a top surface 124 of the second patterned gate 122. The patterning step may comprise steps of forming a patterned photoresist (not shown) on the first spacer material film 116, removing a portion of first spacer material film 116 exposed by an opening of the patterned photoresist, and then removing the patterned photoresist. In some embodiments, before the patterned photoresist is removed, a LDD doping step is performed to the substrate 102 outside of the second patterned gate 122 in the second device region 108 by using the patterned photoresist as a mask layer.

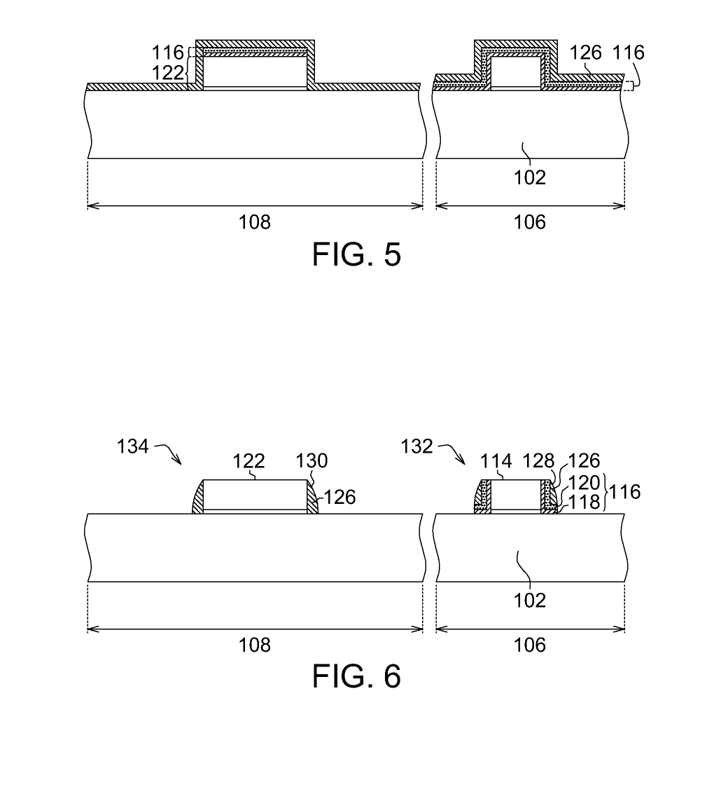

Referring to FIG. 5, a second spacer material film 126 is formed on the first spacer material film 116 and the substrate 102 in the first device region 106, and the second patterned gate 122, the first spacer material film 116 and the substrate 102 in the second device region 108.

Referring to FIG. 6, a portion of the first spacer material film 116 and the second spacer material film 126 is removed to form a first spacer structure 128 on a sidewall of the first patterned gate 114 in the first device region 106 and a second spacer structure 130 on a sidewall of the second patterned gate 122 in the second device region 108. The portion of the first spacer material film 116 and the second spacer material film 126 may be removed by an etching step, comprising a wet etching method, a dry etching method, or other suitable methods. In one embodiment, the first spacer material film 116 (FIG. 5) on the top surface 124 of the second patterned gate 122 is also removed by this etching step.

As shown in FIG. 6, the first spacer structure 128 of a first gate structure 132 has a multi-layer structure consisting of the first spacer material film 116 and the second spacer material film 126. The second spacer structure 130 of a second gate structure 134 has a single-layer structure consisting of the second spacer material film 126. The first dielectric film 118 and the second dielectric film 120 of the first spacer material film 116 of the first spacer structure 128 both have a L shape. The second spacer material film 126 of the first spacer structure 128 and the second spacer material film 126 of the second spacer structure 130 have a D shape.

Accordingly, the first spacer structure 128 and the second spacer structure 130 having different structure characteristics can be formed by the simple method according to concepts of embodiments. In other embodiments, for example, the first spacer structure 128 and the second spacer structure 130 may be adjusted by varying numbers or materials of dielectric films.

In embodiments, process for other elements of the semiconductor devices may be performed between or following the steps as shown in FIGS. 1˜6. For example, the substrate 102 outside of the first gate structure 132 or the second gate structure 134 may be heavily doped to form a source and a drain (not shown). An inter-layer dielectric (not shown) may be formed to cover the substrate 102, the first gate structure 132 and the second gate structure 134. A contact via (not shown) may be formed through the inter-layer dielectric to electrically connect to the source/drain, etc.

Referring to FIG. 6, in one embodiment, the first spacer structure 128 in the first device region 106 for a logic device contains a nitride material. For example, the first spacer structure 128 has an ONO structure. In this case, the first dielectric film 118 of the first spacer material film 116 is an oxide film without a nitride material, such as silicon oxide (SiO), etc. The second dielectric film 120 of the first spacer material film 116 is a nitride-containing film, such as silicon oxynitride (SiON), silicon nitride (SiN), or carbon doped silicon nitride (SiCN), etc. The second spacer material film 126 is an oxide film without a nitride material, such as silicon oxide (SiO), etc. The nitride-containing film may be formed by a deposition method using source gases, for example, comprising 4DMAS (tetrakisdimethylaminosilane; Si[N(CH₃)₂]₄), 3DMAS (trisdimethylaminosilane; Si[N(CH₃)₂]₃H), 2DEAS (bisdiethylaminosilane; Si[N(C₂H₅)₂]₂H₂), and BTBAS (bistertiarybutylaminosilane; SiH₂[NH(C₄H₉)]₂), etc. The oxide film without a nitride material may be formed by a deposition method using source gases, for example, comprising tetra ethoxy silane (TEOS), hexa methyl disiloxane (HMDSO), tetra methyl cyclotetrasiloxane (TMCTS) or Octo methyl cyclotetrasiloxane (OMCTS), etc. Those films may be formed by a CVD method, a PVD method, or other suitable methods.

In one embodiment, the second spacer material film 126 of the second spacer structure 130 in the second device region 108 for a memory device is a no-nitride-containing film, and therefore a non-volatile memory having the second gate structure 134 can have better operating characteristics (e.g. better data retention ability and higher reliability) than a non-volatile memory of a comparative example that has a nitride-containing spacer material film on a sidewall of a patterned gate. In one embodiment, the second spacer material film 126 of the second spacer structure 130 is an oxide film without a nitride material, such as silicon oxide (SiO), etc. In some embodiments, the non-volatile memory formed in the second device region 108 may be a multi-time programmable (MTP) memory or a one-time programmable memory (OTP) memory.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for forming a semiconductor structure, comprising:
forming a gate material film on a substrate in a first device region and a second device region;
patterning the gate material film to form a first patterned gate in the first device region;
forming a first spacer material film on the first patterned gate in the first device region and the gate material film in the second device region;
patterning the first spacer material film and the gate material film to form a second patterned gate in the second device region;
forming a second spacer material film on the first spacer material film in the first device region and the second patterned gate in the second device region; and
removing a portion of the first spacer material film and the second spacer material film to form a first spacer structure consisting of the first spacer material film and the second spacer material film on a sidewall of the first patterned gate in the first device region and a second spacer structure consisting of the second spacer material film on a sidewall of the second patterned gate in the second device region.

2. The method for forming the semiconductor structure according to claim 1, wherein after the step of patterning the first spacer material film and the gate material film to form the second patterned gate in the second device region, a remained first spacer material film in the second device region is only on a top surface of the second patterned gate.

3. The method for forming the semiconductor structure according to claim 2, further comprising removing the remained first spacer material film in the second device region.

4. The method for forming the semiconductor structure according to claim 1, wherein the gate material film is formed by a method comprising:
forming a dielectric layer on the substrate; and
forming an electrode layer on the dielectric layer.

5. The method for forming the semiconductor structure according to claim 1, wherein the first spacer material film has a multi-layer structure, the second spacer material film has a single-layer structure.

6. The method for forming the semiconductor structure according to claim 1, wherein the second patterned gate is formed after the first patterned gate is formed.

7. The method for forming the semiconductor structure according to claim 1, wherein the first spacer material film of the first spacer structure has a L shape, the second spacer material film of the first spacer structure and the second spacer material film of the second spacer structure have a D shape.

8. A method for forming a semiconductor structure, comprising:
forming a gate material film on a substrate in a first device region and a second device region;
patterning the gate material film in the first device region to form a first patterned gate;
forming a first spacer material film containing a nitride material on the first patterned gate in the first device region and the gate material film in the second device region; and
patterning the first spacer material film and the gate material film in the second device region to form a second patterned gate.

9. The method for forming the semiconductor structure according to claim 8, wherein the first device region is for a logic device, the second device region is for a memory device.

10. The method for forming the semiconductor structure according to claim 8, further comprising:
forming a second spacer material film on the first spacer material film in the first device region and the second patterned gate in the second device region; and
removing a portion of the first spacer material film and the second spacer material film to form a first spacer structure on a sidewall of the first patterned gate in the first device region and a second spacer structure on a sidewall of the second patterned gate in the second device region.

11. The method for forming the semiconductor structure according to claim 8, wherein the second spacer material film contains no nitride material.

12. The method for forming the semiconductor structure according to claim 8, wherein the first spacer structure consists of the first spacer material film and the second spacer material film, the second spacer structure consists of the second spacer material film.

13. A semiconductor structure, comprising:
a first patterned gate on a substrate in a first device region;
a second patterned gate on the substrate in a second device region;
a first spacer structure on a sidewall of the first patterned gate, the first spacer structure consisting of a first spacer material film and a second spacer material film on the first spacer material film; and
a second spacer structure on a sidewall of the second patterned gate, the second spacer structure consisting of the second spacer material film.

14. The semiconductor structure according to claim 13, wherein the first spacer material film has a multi-layer structure, the second spacer material film has a single-layer structure.

15. The semiconductor structure according to claim 13, wherein the first spacer material film of the first spacer structure has a L shape, the second spacer material film of the first spacer structure and the second spacer material film of the second spacer structure have a D shape.

16. The semiconductor structure according to claim 13, wherein the first device region is for a logic device, the second device region is for a memory device.

17. The semiconductor structure according to claim 13, wherein the first spacer material film contains a nitride material, the second spacer material film contains no nitride material.

18. The semiconductor structure according to claim 17, wherein the second spacer material film is an oxide film without a nitride material.
